(19) United States
(12) Patent Application Publication
(10) Pub. No.: US 2012/0320551 A1
(43) Pub. Date: Dec. 20, 2012

(54) EXPANSION STRUCTURE

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/413,220

(22) Filed: Mar. 6, 2012

(30) Foreign Application Priority Data
Jun. 20, 2011 (CN) 201110165764.2

(51) Int. Cl. H05K 7/02

(52) U.S. Cl. 361/785

(57) ABSTRACT

An expansion structure is used for electrically connecting an expansion card to a motherboard and includes a flexible printed circuit board (FPC) and a connection board. The FPC is electrically connected to the motherboard. One end of the FPC is electrically connected to the motherboard, another end of the FPC is electrically connected to the connection board. The connection board is electrically connected to the expansion card as the FPC permits deformation, and the expansion card is electrically connected to the motherboard through the connection board and the FPC.

### BACKGROUND

1. Technical field

The disclosure generally relates to circuit boards, and more particularly to a expansion structure used for connecting expansion cards to a motherboard.

2. Description of the Related Art

Expansion structures allow expansion cards to be added to a computer or server system to add functionality to the computer or server system. The expansion structures with expansion cards are electrically connected to a motherboard of the computer system through connectors (e.g., PCI-Express connectors). However, the installation position of the expansion structure with expansion card relative to the motherboard must be fixed, therefore, the adjustment of the expansion structure on account of the location of the connectors is generally not possible, limiting the layout of the expansion cards.

Therefore, there is room for improvement within the art.

### BRIEF DESCRIPTION OF THE DRAWINGS

Many aspects of an expansion structure can be better understood with reference to the drawings. The components in the drawings are not necessarily drawn to scale, the emphasis instead being placed upon clearly illustrating the principles of the expansion structure. Moreover, in the drawings, like reference numerals designate corresponding parts throughout the several views. Wherever possible, the same reference numbers are used throughout the drawings to refer to the same or like elements of an embodiment.

FIG. 1 is an exploded schematic view of an expansion structure used to connect an expansion card to a motherboard, according to a first embodiment of the disclosure.

FIG. 2 is an enlarged schematic view of a flexible printed circuit board of the expansion structure shown in FIG. 1 of the disclosure.

FIG. 3 is an assembled schematic view of the expansion structure with the expansion card and the motherboard shown in FIG. 1 of the disclosure.

FIG. 4 is an exploded schematic view of an expansion structure that connects an expansion card to a motherboard, according to a second embodiment of the disclosure.

FIG. 5 is an assembled schematic view of the expansion structure with the expansion card and the motherboard shown in FIG. 4 of the disclosure.

### DETAILED DESCRIPTION

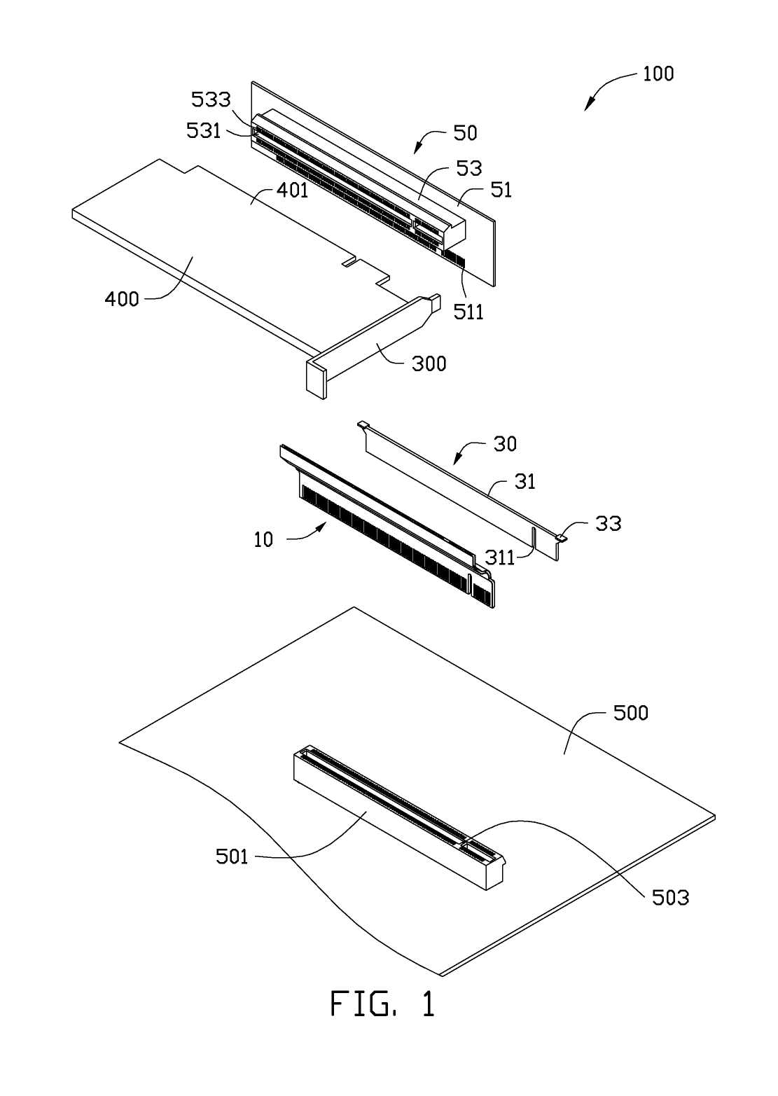

FIG. 1 is an exploded schematic view of an expansion structure 100 used to connect an expansion card 400 to a motherboard 500, according to a first embodiment of the disclosure. The expansion structure 100 can be plugged into a system board of a computer or server, and can provide additional slots for expansion cards and allow the addition of extra functional cards in various desired positions.

The expansion structure 100 includes a flexible printed circuit board (FPC) 10, a mounting board 30, and a connection board 50. The mounting board 30 is assembled to an end of the FPC 10 by, for example, adhesives. The connection board 50 is assembled to another end of the FPC 10. Thus, the connection board 50 can be positioned at any desired angle relative to the mounting board 30 by using the flexibility of the FPC 10.

The expansion card 400 includes a plug section 401. The plug section 401 is detachably received within the connection board 50 and is electrically connected to the connection board 50. The expansion card 400 is fixed within the computer through a fixing frame 300 and is adjacent to the expansion structure 100. The motherboard 500 includes a connector 501 electrically connected to the FPC 10, and the connector 501 includes a positioning portion 503 in the connector 501. In this embodiment, the connector 501 can be a peripheral component interconnect express (PCIE) connector.

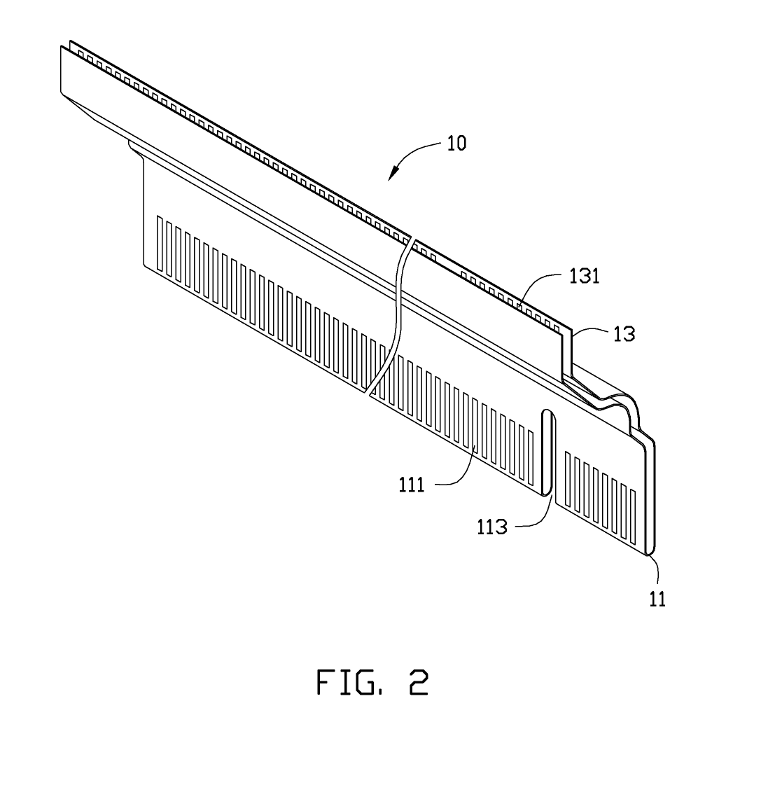

Further referring to FIG. 2, the FPC 10 can be deformed into a number of desired shapes, and includes an electrical plug 11 and an electrical slot 13 located at opposite ends of the FPC 10. The electrical plug 11 is detachably and electrically connected to the connector 501 of the motherboard 500, and the electrical slot 13 is detachably and electrically connected to the connection board 50. Thus, the connection board 50 can be electrically connected to the motherboard 500 through the FPC 10.

The electrical plug 11 includes a plurality of metallic electrical contacts 111 and a gap 113. The metallic electrical contacts 111 are made of a metallic such as copper, or metallic, to enable electrical connections between the FPC 10 and the motherboard 500. The gap 113 is aligned with the positioning portion 503 of the motherboard 500 to ensure the correct assembly of the FPC 10 on the motherboard 500. The electrical slot 13 includes a plurality of metallic electrical contacts 131. The metallic electrical contacts 131 are made of a metallic such as copper, or metallic, to form electrical connections between the FPC 10 and the connection board 50.

The FPC 11 can be a single-layer FPC or double-layer FPC, and the FPC 11 can be made by doubling up a symmetrical FPC to form a double-layer FPC. In this embodiment, the FPC 11 is a double-layer FPC. The metallic electrical contacts 111 are located on opposite outer surfaces of the electrical plug 11, and the metallic electrical contacts 131 are arranged on opposite inner surfaces of the electrical slot 13. Additionally, when the FPC 11 is a single-layer FPC, the metallic electrical contacts 111 and 131 are respectively arranged on each surface of the electrical plugs 11 and 13.

The mounting board 30 includes a main body 31 and two operation sections 33 located at the opposite ends of the main body 31. The main body 31 is a rectangular plate and defines an opening 311 corresponding to the gap 113 of the electrical plug 11. The main body 31 is fixed within the electrical plug 11 by means of adhesive for example to enhance the structural strength of the electrical plug 11, then the opening 311 is aligned with the gap 113. The two operation sections 33 are exposed from the electrical plug 11 and can be inserted into or unplugged from the connector 501 of the motherboard 500.

The connection board 50 is electrically connected between the expansion card 400 and the FPC 10 to form electrical connection between the expansion card 400 and the motherboard 500. The connection board 50 includes a circuit board 51 and a connection port 53 electrically connected to the circuit board 51. The circuit board 51 includes a plurality of metallic contacts 511 at the opposite sides of one end of the circuit board 51, and the metallic contacts 511 are aligned with the metallic electrical contacts 131 of the electrical slot 13. Thus, when the circuit board 51 is received within the electrical slot 13, the metallic contacts 511 electrically connect to the metallic electrical contacts 131, and the connection board 50 is thus electrically connected to the FPC 10.

The connection port 53 is located at another end of the circuit board 51, and includes a socket 531 and a plurality of elastic sheets 533 in the socket 531. The socket 531 corresponds to the plug section 401 of the expansion card 400 in shape and size, and the plug section 401 can be electrically received within the socket 531. When the plug section 401 is inserted into the socket 531, the plug section 401 contacts the elastic sheets 533, and the connection board 50 is thus electrically connected to the expansion card 400.

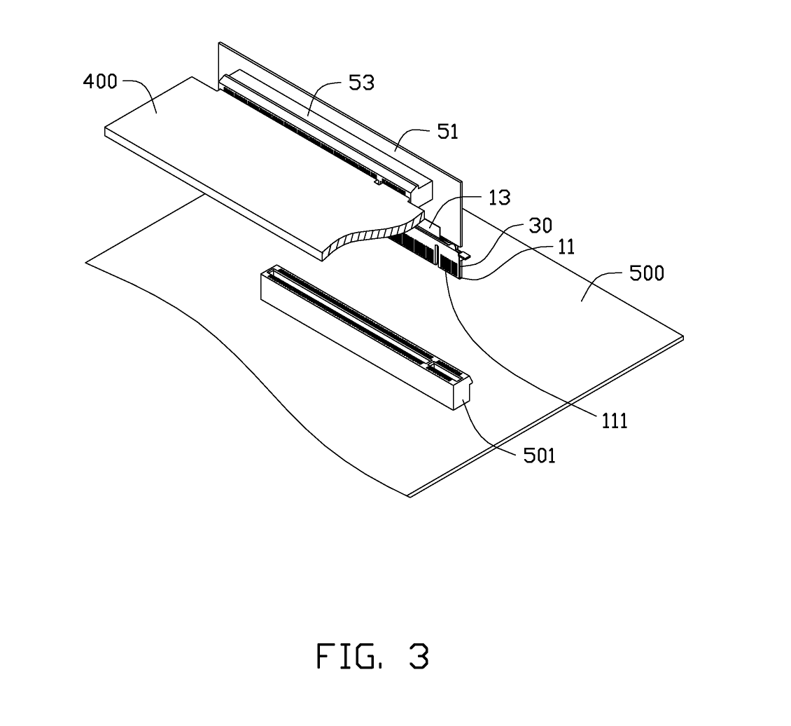

Referring to FIG. 3, in assembly, the main body 31 is positioned within the electrical plug 11, the opening 311 is aligned with the gap 113, and the two operation sections 33 are exposed from the opposite ends of the electrical plug 11. By pressing the operation sections 33, the electrical plug 11 with the main body 31 is inserted into the connector 501 of the motherboard 500, thus forming electrical connections between the FPC 10 and the motherboard 500. The circuit board 51 is received in the electrical slot 13 of the FPC 10, and the connection board 50 is electrically connected to the FPC 10. The expansion card 400 is fixed on the fixing frame 300 and is adjacent to the expansion structure 100. By moving the connection board 50, the FPC 10 then deforms, and the socket 531 of the connection port 53 is aligned with the plug section 401, the plug section 401 is electrically connected to the socket 531. Thus, the expansion card 400 electrically connects to the motherboard 500 through the connection board 50 and the FPC 10.

In addition, the connection board 50 can be moved as the FPC 10 permits a high degree of deformation. Accordingly, the plug section 401 moves out from the socket 531 of the connection port 53. Then the expansion card 400 is detached from the fixing frame 300.

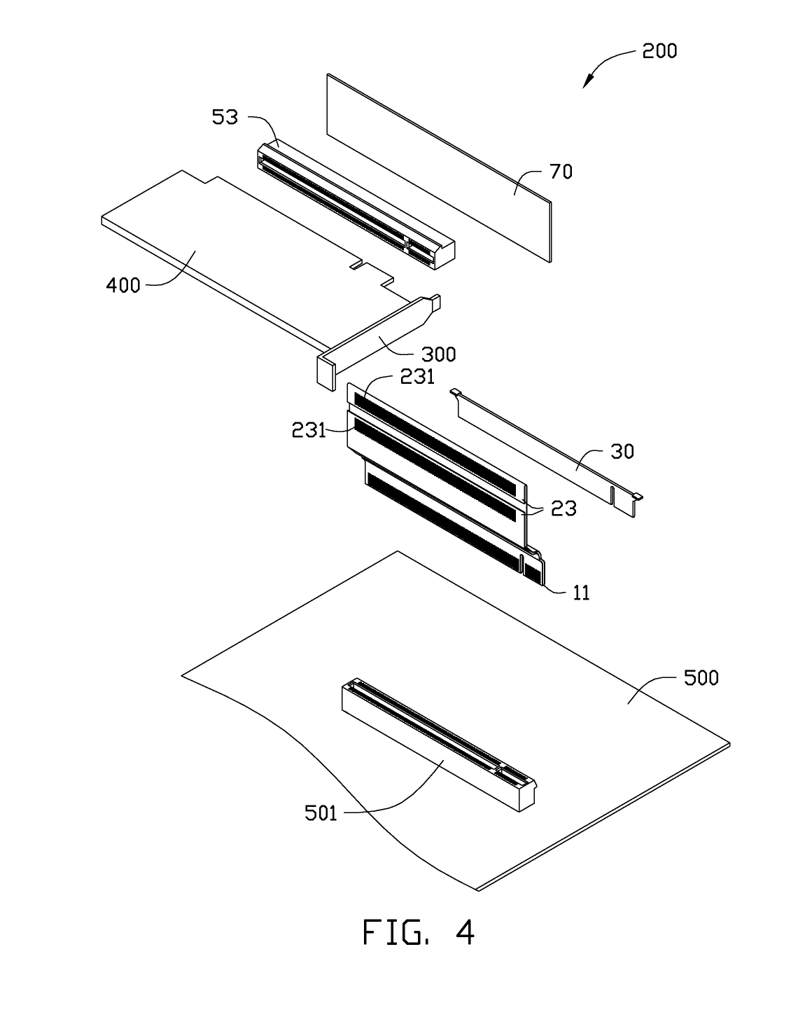

FIG. 4 is an exploded schematic view of an expansion structure 200 used to connect an expansion card 400 to a motherboard 500, according to a second embodiment of the disclosure. The expansion structure 200 in this embodiment is substantially similar to the expansion structure 100 of the first embodiment.

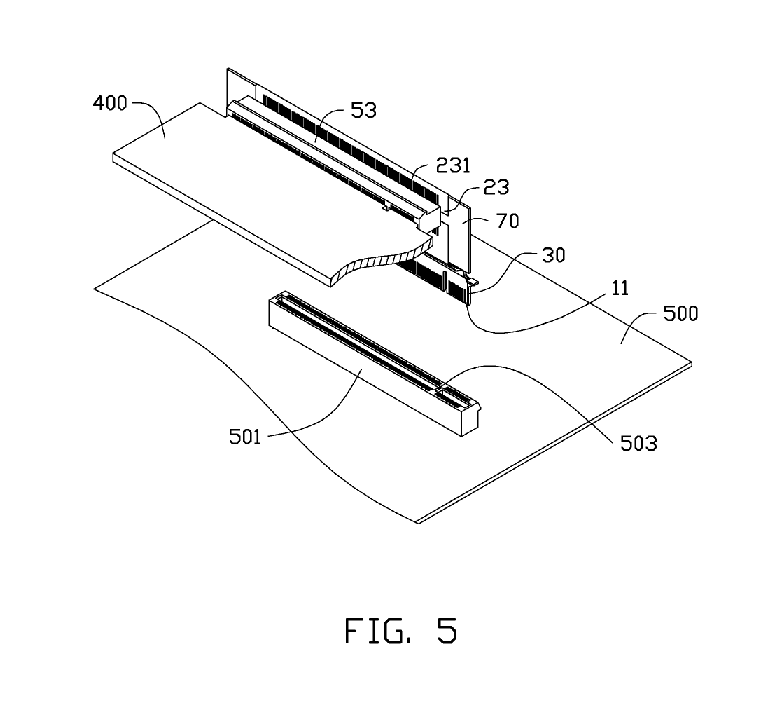

Referring to FIG. 5, the circuit board 51 of the connection board 50 is omitted, and the FPC 10 includes an electrical slot 23. The electrical slot 23 includes two groups of metallic electrical contacts at the outer surface of the electrical slot 23, and each group of metallic electrical contacts includes a plurality of metallic electrical contacts 231. A holding plate 70 is located within the electrical slot 23, by adhesive for example, to enhance the structure strength of the electrical slot 23 and secure the connection port 53. The two groups of metallic electrical contacts are electrically connected to the electrical plug 11, the connection port 53 is positioned on the electrical slot 23 by implementing, for example, surface mount technology (SMT), and electrically contacts the two groups of metallic electrical contacts 231. Thus, the expansion card 400 is electrically connected to the motherboard 500 through the connection board 50 and the FPC 10.

When the electrical plug 11 of the FPC 10 is inserted into the connector 501 of the motherboard 500, the electrical slot 13 can flex to a desired orientation, angle or shape relative to the electrical plug 11. Thus, the connection board 50 on the electrical slot 13 can electrically connect to different expansion cards 400 on the motherboard 500, enhancing the freedom of design and the actual layout of the expansion cards 400.

In the present specification and claims, the word “a” or “an” preceding an element does not exclude the presence of a plurality of such elements. Further, the word “comprising” does not exclude the presence of other elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. An expansion structure used for electrically connecting an expansion card to a motherboard, the expansion structure comprising:
a flexible printed circuit board (FPC) electrically connected to the motherboard; and
a connection board;
wherein one end of the FPC is electrically connected to the motherboard, another end of the FPC is electrically connected to the connection board, the connection board electrically connects to the expansion card by deforming the FPC, and the expansion card electrically connects to the motherboard through the connection board and the FPC.

2. The expansion structure as claimed in claim 1, wherein the FPC comprises an electrical plug and an electrical slot, the electrical plug is located at one end of the FPC and is electrically connected to a connector of the motherboard, and the electrical slot is located at another end of the FPC and electrically connects to the connection board, and the connection board is electrically connected to the motherboard through the FPC.

3. The expansion structure as claimed in claim 2, wherein the electrical plug comprises a plurality of metallic electrical contacts and a gap, the metallic electrical contacts enable an electrical connection between the FPC and the motherboard, and the gap is aligned with a positioning portion of the connector to ensure the FPC is correctly assembled on the motherboard.

4. The expansion structure as claimed in claim 2, wherein the electrical slot comprises a plurality of metallic electrical contacts, and the metallic electrical contacts are made of metallic to form an electrical connection between the FPC and the connection board.

5. The expansion structure as claimed in claim 3, further comprising a mounting board located at the electrical plug, wherein the connection board can be bent into a desired angle relative to the mounting board due to the flexibility of the FPC.

6. The expansion structure as claimed in claim 5, wherein the mounting board comprises a main body and two operation sections located at the opposite ends of the main body, the main body is fixed within the electrical plug by means of adhesive to enhance the structure strength of the electrical plug, and the two operation sections are exposed from the electrical plug and are capable of inserting or unplugging the electrical plug into or from the connector of the motherboard.

7. The expansion structure as claimed in claim 6, wherein the main body defines an opening corresponding the gap of the electrical plug, when the main body is fixed within the electrical plug, the opening is aligned with the gap.

8. The expansion structure as claimed in claim 4, wherein the connection board comprises a circuit board and a connection port, the circuit board comprises a plurality of metallic contacts at one end of the circuit board, the metallic contacts are aligned with the metallic electrical contacts of the electrical slot, when the circuit board is received within the electrical slot, the metallic contacts electrically contact the metallic electrical contacts of the electrical slot respectively, and the connection port is electrically connected to the other end of the circuit board and is electrically connected to the expansion card.

9. The expansion structure as claimed in claim 2, wherein the electrical slot comprises two groups of metallic electrical contacts at the outer surface of the electrical slot, each group of metallic electrical contacts comprises a plurality of metallic electrical contacts, and the two groups of metallic electrical contacts are electrically connected to the electrical plug.

10. The expansion structure as claimed in claim 9, further comprising a holding plate, wherein the connection board comprises a connection port, the holding plate is located within the electrical slot to enhance the structure strength of the electrical slot, and the connection port is positioned on the electrical slot, and electrically contacts the metallic electrical contacts of the electrical slot, and the expansion card is electrically connected to the motherboard through the connection board and the FPC.

11. The expansion structure as claimed in claim 2, wherein the FPC is a single-layer FPC or double-layer FPC, or is made by doubling up a symmetrical FPC, and when the electrical plug of the FPC is inserted into the connector of the motherboard, the electrical slot flex to a determined or desired orientation, angle or shape relative to the electrical plug.

12. An expansion structure used to form electrical connections between an expansion card and a motherboard, and the expansion card fixed on the motherboard via a fixing frame, the expansion structure, comprising:
a flexible printed circuit board (FPC) electrically connected to the motherboard and comprising:
an electrical plug; and
an electrical slot that is bent into a desired angle relative to the electrical plug; and
a connection board, wherein the FPC is electrically connected to the motherboard through the electrical plug, the FPC is electrically connected to the connection board via the electrical slot, the connection board is electrically connected to or disconnected from the expansion card by deforming the FPC, and the expansion card is electrically connected to the motherboard through the connection board and the FPC.

13. The expansion structure as claimed in claim 12, wherein the electrical plug is located at an end of the FPC and electrically connected to a connector of the motherboard, and the electrical slot is located at another end of the FPC and electrically connects to the connection board, the connection board electrically connects to the motherboard through the FPC.

14. The expansion structure as claimed in claim 13, wherein the electrical plug comprises a plurality of metallic electrical contacts and a gap, the metallic electrical contacts are made of metal metallic to enable an electrical connection between the FPC and the motherboard, and the gap is aligned with a positioning portion of the connector to ensure the FPC is correctly assembled on the motherboard, and the electrical slot comprises a plurality of metallic electrical contacts, and the metallic electrical contacts of the electrical slot form an electrical connection between the FPC and the connection board.

15. The expansion structure as claimed in claim 14, further comprising a mounting board located at the electrical plug, wherein the mounting board comprises a main body and two operation sections located at the opposite ends of the main body, the main body is fixed within the electrical plug by means of adhesive to enhance the structure strength of the electrical plug, and the two operation sections are exposed from the electrical plug and are capable of inserting or unplugging the electrical plug into or from the connector of the motherboard.

16. The expansion structure as claimed in claim 15, wherein the main body defines an opening corresponding the gap of the electrical plug, when the main body is fixed within the electrical plug, the opening is aligned with the gap.

17. The expansion structure as claimed in claim 15, wherein the connection board comprises a circuit board and a connection port, the circuit board comprises a plurality of metallic contacts at one end of the circuit board, the metallic contacts are aligned with the metallic electrical contacts of the electrical slot, when the circuit board is received within the electrical slot, the metallic contacts electrically contact the metallic electrical contacts of the electrical slot respectively, and the connection port is electrically connected to the other end of the circuit board and is electrically connected to the expansion card.

18. The expansion structure as claimed in claim 13, wherein the electrical slot comprises two groups of metallic electrical contacts at the outer surface of the electrical slot, each group of metallic electrical contacts comprises a plurality of metallic electrical contacts, and the two groups of metallic electrical contacts are electrically connected to the electrical plug.

19. The expansion structure as claimed in claim 18, further comprising a holding plate, wherein the connection board comprises a connection port, the holding plate is located within the electrical slot to enhance the structure strength of the electrical slot, and the connection port is positioned on the electrical slot, and electrically contacts the metallic electrical contacts of the electrical slot, and the expansion card is electrically connected to the motherboard through the connection board and the FPC.

20. The expansion structure as claimed in claim 13, wherein the FPC is a single-layer FPC or double-layer FPC, or is made by doubling up a symmetrical FPC, and when the electrical plug of the FPC is inserted into the connector of the motherboard, the electrical slot is flexibly bent or deformed into a determined or desired orientation, angle or shape relative to the electrical plug.
